(19) United States
(12) Patent Application Publication
(10) Pub. No.: US 2020/0026133 A1
(43) Pub. Date: Jan. 23, 2020

(54) ARRAY SUBSTRATE AND METHOD OF MANUFACTURING THE SAME, DISPLAY PANEL AND METHOD OF MANUFACTURING THE SAME, DISPLAY DEVICE

(71) Applicant: BOE TECHNOLOGY GROUP CO., LTD., Beijing (CN)

(72) Inventors: Hongrun Wang, Beijing (CN); Ming Zhu, Beijing (CN)

(21) Appl. No.: 16/335,649

(22) PCT Filed: May 30, 2018
(86) PCT No.: PCT/CN2018/089005

§ 371 Date: Mar. 21, 2019

(30) Foreign Application Priority Data
Aug. 28, 2017 (CN) 201710752621.9

(51) Int. Cl. G02F 1/1362; G02F 1/1368; H01L 27/12; G02F 1/1335

(52) U.S. Cl. CPC G02F 1/136209; G02F 1/136286; G02F 1/133514; H01L 27/124; G02F 1/1368

(57) ABSTRACT

An array substrate and a method of manufacturing the same, a display panel and a method of manufacturing the same, and a display device are provided. The an array substrate includes a base substrate and a plurality of pixels on the base substrate, at least one of the plurality of pixels includes a reflective layer on the base substrate; a filter layer on a side of the reflective layer away from the base substrate; and a pixel electrode on a side of the filter layer away from the reflective layer.

### CROSS-REFERENCE TO RELATED APPLICATION

This application is a Section 371 National Stage Application of International Application No. PCT/CN2018/089005, filed on May 30, 2018. This application claims the benefit of Chinese Patent Application No. 201710752621.9 filed on Aug. 28, 2017 in the State Intellectual Property Office of China, the whole disclosure of which is incorporated herein by reference.

### TECHNICAL FIELD

The present disclosure relates to the field of display technology, and in particular, to an array substrate and a method of manufacturing the same, a display panel and a method of manufacturing the same, and a display device.

### BACKGROUND

A display device is a device for displaying characters, numbers, symbols, or pictures, or for displaying images formed by combining at least two of characters, numbers, symbols, and pictures, and provides great convenience for people's life and work. Display devices usually include a display panel. A general display panel, such as a liquid crystal display panel, generally includes an array substrate, a color filter substrate, and a liquid crystal layer between the array substrate and the color filter substrate. The color display of the display device is realized by the action of a filter layer of the color filter substrate on the light passing through the liquid crystal layer. However, due to the manufacturing process, the type of the display panel, etc., when the display panel is in use, the filter layer cannot completely cover a corresponding pixel region except a thin film transistor (i.e., an effective display region of the pixel region). For example, for a flexible reflective display panel, when it is bent, the filter layer in a bend region of the flexible reflective display panel may not completely cover the corresponding pixel region except the thin film transistor, thereby causing light leakage from the display panel.

### SUMMARY

According to an aspect of the present disclosure, an embodiment provides an array substrate comprising: a base substrate and a plurality of pixels on the base substrate, at least one of the plurality of pixels includes: a reflective layer on the base substrate; a filter layer on a side of the reflective layer away from the base substrate; and a pixel electrode on a side of the filter layer away from the reflective layer.

In some embodiments, the array substrate further comprising: a thin film transistor between the base substrate and the reflective layer, wherein at least one of the reflective layer and the filter layer covers at least a portion of the thin film transistor.

In some embodiments, the array substrate further comprising: a plurality of gate lines; a plurality of data lines crossing the plurality of gate lines; and a black matrix on a side of the thin film transistor away from the base substrate, wherein the plurality of data lines and the plurality of gate lines crossing each other define a plurality of first regions, the black matrix defines a plurality of opening regions, and an orthographic projection of each of the first regions on the base substrate falls within an orthographic projection of an corresponding one of the opening regions on the base substrate.

In some embodiments, the array substrate further comprising: a plurality of gate lines; a plurality of data lines crossing the plurality of gate lines; and a black matrix on a side of the thin film transistor away from the base substrate, wherein the plurality of data lines and the plurality of gate lines crossing each other define a plurality of first regions, the black matrix defines a plurality of opening regions, and an orthographic projection of each of the first regions on the base substrate substantially coincides with an orthographic projection of an corresponding one of the opening regions on the base substrate.

In some embodiments, the at least one of the plurality of pixels comprises one of the plurality of first regions and one of plurality of opening regions, and an orthographic projection of at least one of the reflective layer and the filter layer on the base substrate substantially coincides with an orthographic projection of the plurality of opening regions on the base substrate.

In some embodiments, the reflective layer and the filter layer are both disposed in the one of the plurality of opening regions, and an orthographic projection of each of the reflective layer and the filter layer on the base substrate substantially coincides with the orthographic projection of the one of the plurality of opening regions on the base substrate.

In some embodiments, reflective layers of the plurality of pixels are connected to each other to form an integrated continuous reflective layer, an orthographic projection of the integrated continuous reflective layer on the base substrate substantially completely covers the base substrate, and the black matrix and the filter layer are both disposed on a side of the integrated continuous reflective layer away from the base substrate, the filter layer is disposed in the one of the plurality of opening regions, the orthographic projection of the filter layer on the base substrate substantially coincides with the orthographic projection of the one of the plurality of opening regions on the base substrate.

In some embodiments, the array substrate further comprising: a common electrode on a side of the filter layer away from the reflective layer.

In some embodiments, the reflective layer is a metal reflective layer.

In some embodiments, the array substrate further comprising: a passivation layer between the integrated continuous reflective layer and the black matrix.

In some embodiments, the common electrode is between the pixel electrode and the reflective layer.

According to another aspect of the present disclosure, an embodiment provides a display panel comprising: the array substrate of any one of the above embodiments; and an opposite substrate in parallel with and opposite to the array substrate, the opposite substrate being on a side of the pixel electrode away from the base substrate, wherein a common electrode is disposed on a surface of the opposite substrate facing the array substrate.

According to another aspect of the present disclosure, an embodiment provides a display panel comprising: the array substrate of the above embodiments; and an opposite substrate in parallel with and opposite to the array substrate, the opposite substrate being on a side of both the pixel electrode and the common electrode away from the base substrate.

According to another aspect of the present disclosure, an embodiment provides a display device comprising the display panel of the above embodiments.

According to another aspect of the present disclosure, an embodiment provides a method of manufacturing an array substrate, comprising: providing a base substrate; forming a reflective layer on the base substrate; forming a filter layer on a side of the reflective layer away from the base substrate; and forming a pixel electrode on a side of the filter layer away from the reflective layer.

In some embodiments, before forming a reflective layer on the base substrate, the method further comprises: forming a thin film transistor on the base substrate, wherein the reflective layer is disposed on a side of the thin film transistor away from the base substrate, and at least one of the reflective layer and the filter layer covers at least a portion of the thin film transistor.

In some embodiments, the method further comprising: forming a plurality of gate lines on the base substrate; forming a plurality of data lines crossing the plurality of gate lines on the base substrate; and forming a black matrix on the side of the thin film transistor away from the base substrate, wherein the plurality of data lines and the plurality of gate lines crossing each other define a plurality of first regions, and the black matrix defines a plurality of opening regions, wherein an orthographic projection of each of the first regions on the base substrate falls within an orthographic projection of an corresponding one of the opening regions on the base substrate, or the orthographic projection of each of the first regions on the base substrate coincides with the orthographic projection of the corresponding one of the opening regions on the base substrate.

In some embodiments, the black matrix is formed before forming the reflective layer, and the reflective layer and the filter layer are both formed in one of the plurality of opening regions, and an orthographic projection of each of the reflective layer and the filter layer on the base substrate substantially coincides with the orthographic projection of the one of the plurality of opening regions on the base substrate.

In some embodiments, the black matrix is formed after forming the reflective layer and before forming the filter layer, and an orthographic projection of the reflective layer on the base substrate substantially completely covers the base substrate, and both the black matrix and the filter layer are disposed on a side of the reflective layer away from the base substrate, the filter layer is disposed in one of the plurality of opening regions, an orthographic projection of the filter layer on the base substrate substantially coincides with the orthographic projection of the one of the plurality of opening regions on the base substrate.

In some embodiments, the method further comprising: forming a common electrode on a side of the filter layer away from the reflective layer.

According to another aspect of the present disclosure, an embodiment provides a method of manufacturing a display panel, comprising: forming the array substrate by using the method of any one of the above embodiments; providing an opposite substrate, and forming a common electrode on the opposite substrate; and aligning and assembling the array substrate and the opposite substrate.

According to another aspect of the present disclosure, an embodiment provides a method of manufacturing a display panel, comprising: forming the array substrate by using the method of the above embodiments; providing an opposite substrate; and aligning and assembling the array substrate and the opposite substrate.

### BRIEF DESCRIPTION OF THE DRAWINGS

The drawings described herein are intended to provide a further understanding of the disclosure, and constitute a part of the present disclosure. The illustrated embodiments of the present disclosure and the description thereof are provided to assist in explanation of the present disclosure, but do not constitute all possible embodiments according to this disclosure, and should not be understood as limiting or exhaustive. In the drawings:

FIG. 1 is a schematic cross-sectional view of an array substrate according to an embodiment of the present disclosure;

FIG. 2 is a schematic plan view showing a layout of a reflective layer of the array substrate of FIG. 1;

FIG. 3 is a schematic plan view showing a layout of a reflective layer of the array substrate of FIG. 1;

FIG. 4 is a schematic cross-sectional view of another array substrate according to an embodiment of the present disclosure;

FIG. 5 is a schematic plan view showing a layout of a reflective layer of the array substrate of FIG. 4;

FIG. 6 is a schematic plan view showing a layout of a reflective layer of the array substrate of FIG. 4;

FIG. 7 is a schematic cross-sectional view of a display panel according to an embodiment of the present disclosure;

FIG. 8 is a schematic cross-sectional view of another display panel according to an embodiment of the present disclosure; and

FIGS. 9-13 are flowcharts showing a method of manufacturing an array substrate according to an embodiment of the present disclosure.

### DETAILED DESCRIPTION OF THE EMBODIMENTS

In order to further explain an array substrate and a manufacturing method thereof, a display panel and a manufacturing method thereof, and a display device provided by the embodiments of the present disclosure, the embodiments will be described in detail below in conjunction with the accompanying drawings.

In order to solve the problem that the filter layer cannot completely cover the corresponding pixel region except the thin film transistor, A COA (Color Filter On Array) technology is used in the related art. The filter layer is integrated in the array substrate, so that the filter layer can completely cover the corresponding pixel region except the thin film transistor when the display panel is bent, thereby avoiding light leakage of the display panel. However, the Applicant has found that, due to restrictions of the structure and operation mode of the display panel in the related art, when a voltage is applied between a pixel electrode and a common electrode in the display panel, respectively, so that an electric field generated between the pixel electrode and the common electrode drives liquid crystal molecules in the liquid crystal layer to deflect, a large voltage is usually required, resulting in an increase in power consumption of the display panel.

An embodiment of the present disclosure provides an array substrate including a base substrate and a plurality of pixels on the base substrate. At least one of the plurality of pixels includes a reflective layer, a filter layer, and a pixel electrode. The reflective layer is disposed on the base substrate, the filter layer is disposed on a side of the reflective layer away from the base substrate, and the pixel electrode is disposed on a side of the filter layer away from the reflective layer. When a display panel including the array substrate of the present disclosure is in operation, an electric field generated between the pixel electrode and a common electrode does not pass through the filter layer, therefore, the filter layer does not adversely affect the electric field generated between the pixel electrode and the common electrode, so that a voltage required to drive the liquid crystal molecules to deflect can be reduced, thereby reducing the power consumption of the display panel.

In the following description, the present disclosure is mainly directed to a pixel structure for expression. A person skilled in the art can understand the specific structure of the entire array substrate including the plurality of pixels.

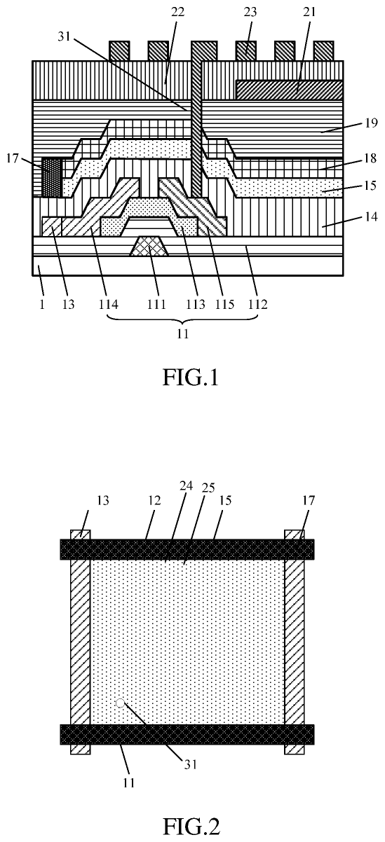

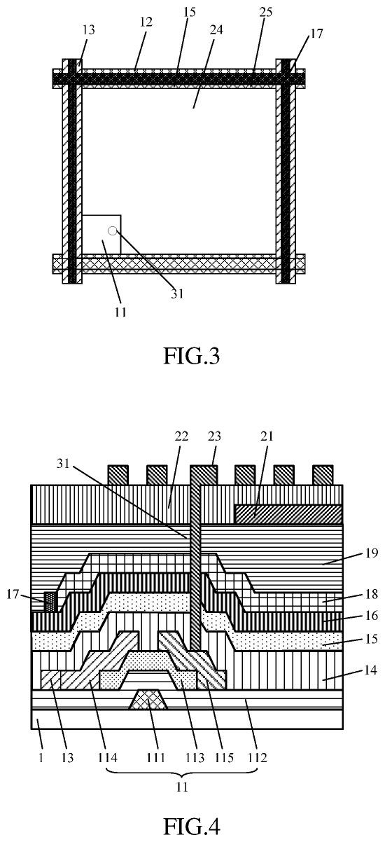

FIG. 1 is a schematic cross-sectional view of an array substrate according to an embodiment of the present disclosure; FIG. 2 is a schematic plan view showing a layout of a reflective layer of the array substrate of FIG. 1; FIG. 3 is a schematic plan view showing a layout of a reflective layer of the array substrate of FIG. 1. Referring to FIGS. 1-3, an embodiment of the present disclosure provides an array substrate including a base substrate 1, a reflective layer 15, a filter layer 18, and a pixel electrode 23 and a common electrode 21. The reflective layer 15 and the filter layer 18 are sequentially disposed on the base substrate 1, that is, the filter layer 18 is located on a side of the reflective layer 15 away from the base substrate 1. The pixel electrode 23 and the common electrode 21 are both located on a side of the filter layer 18 away from the reflective layer 15.

For example, referring to FIGS. 1-3, the array substrate provided by this embodiment is applied to a display panel of a reflective display device. In the array substrate provided in this embodiment, the filter layer 18 is integrated in the array substrate by using COA technology, and the common electrode 21 is also integrated in the array substrate. The array substrate in this embodiment is, for example, an FFS (Fringe Field Switching) mode array substrate.

Specifically, the array substrate provided in this embodiment includes a base substrate 1, a reflective layer 15, a filter layer 18, a pixel electrode 23 and a common electrode 21. The reflective layer 15 and the filter layer 18 are sequentially disposed on the base substrate 1, that is, the filter layer 18 is located on a side of the reflective layer 15 away from the base substrate 1. Both the pixel electrode 23 and the common electrode 21 are located above the filter layer 18, that is, the pixel electrode 23 and the common electrode 21 are located on a side of the filter layer 18 away from the reflective layer 15. The arrangement of the pixel electrode 23 and the common electrode 21 can be set according to actual needs. For example, referring to FIG. 1, the common electrode 21 can be located between the filter layer 18 and the pixel electrode 23. In this case, a third passivation layer 19 is formed on the filter layer 18, then the common electrode 21 is formed on the third passivation layer 19, and then a fourth passivation layer 22 is formed, the fourth passivation layer 22 covering the third passivation layerl9 and the common electrode 21, and then the pixel electrode 23 is formed on the fourth passivation layer 22.

In the array substrate provided in the embodiment, the reflective layer 15 and the filter layer 18 are sequentially disposed on the base substrate 1. Both the pixel electrode 23 and the common electrode 21 are disposed on the side of the filter layer 18 away from the reflective layer 15. When a display panel including the array substrate provided in this embodiment is in operation, a voltage signal is applied between the pixel electrode 23 and the common electrode 21, an electric field generated between the pixel electrode 23 and the common electrode 21 does not pass through the filter layer 18, therefore, the filter layer 18 does not adversely affect the electric field generated between the pixel electrode 23 and the common electrode 21, so that the voltage required to drive the liquid crystal molecules to deflect can be reduced, thereby reducing the power consumption of the display panel.

In addition, in the array substrate provided in the embodiment, the reflective layer 15 functions only to reflect light, and does not function as, for example, an electrode. The reflective layer 15 has a single function, so that the structure of the reflective layer 15 can be conveniently set, and it is also possible to prevent the reflective layer from adversely affecting the potential of the pixel electrode 23 or the common electrode 21 when the reflective layer 15 functions as an electrode.

In this embodiment, the reflective layer 15 may have various structures. For example, please continue to refer to FIG. 1 and FIG. 2, the array substrate provided in this embodiment includes a plurality of first regions 24, the first regions being defined by a plurality of gate lines 12 and a plurality of data lines 13 crossing each other. One thin film transistor 11 is disposed in each of the first regions 24, and each of the first regions 24 corresponds to one pixel electrode 23 and one common electrode 21. A gate electrode 111 of the thin film transistor 11 is electrically connected to a corresponding gate line 12, a source electrode 114 of the thin film transistor 11 is electrically connected to a corresponding data line 13, and a drain electrode 115 of the thin film transistor 11 is connected to a corresponding pixel electrode 23. The thin film transistor 11 is located between the base substrate 1 and the reflective layer 15. An orthographic projection of the reflective layer 15 on the base substrate 1 falls within an orthographic projection of the first region 24 on the base substrate 1, and the reflective layer 15 covers the first region except the thin film transistor 11, and the reflective layer 15 may further cover at least a portion of the thin film transistor 11. For example, the reflective layer 15 may cover the first region 24 except the thin film transistor 11 and a portion of the thin film transistor 11, in this case, the area of the reflective layer 15 is smaller than that of the corresponding first region 24. Alternatively, referring to FIG. 1 and FIG. 2, the orthographic projection of the reflective layer 15 on the base substrate 1 substantially coincides with the orthographic projection of the first region 24 on the base substrate 1, and the reflective layer 15 may substantially cover the entire first region. That is, the reflective layer 15 substantially covers the first region except the thin film transistor 11 and the thin film transistor 11.

Specifically, referring to FIG. 1-3, the thin film transistor 11 is formed in the first region 24 on the base substrate 1. The thin film transistor 11 includes a gate electrode 111, a gate insulating layer 112, an active layer 113, a source electrode 114, and a drain electrode 115. The gate electrode 111 is disposed in the same layer as the gate lines 12, and the gate electrode 111 is electrically connected to a corresponding gate line 12. The gate insulating layer 112 covers the gate electrode 111, the gate line 12 and the base substrate 1, and it is also understood that the gate insulating layer 112 substantially completely covers the base substrate 1 on which the gate electrode 111 and the gate line 12 are formed. As shown in FIG. 1, an orthographic projection of the gate insulating layer 112 on the base substrate 1 substantially completely covers the base substrate 1. The source electrode 114 and the drain electrode 115 are disposed in the same layer as the data lines 13, and the source electrode 114 is electrically connected to a corresponding data line 13, the drain electrode 115 is connected to a corresponding pixel electrode 23. A first passivation layer 14 is formed on the thin film transistor 11. The first passivation layer 14 covers the source electrode 114, the drain electrode 115, the active layer 113, the data line 13, the gate line 12, and the gate insulating layer 112. It can also be understood that the first passivation layer 14 substantially completely covers the base substrate 1 on which the thin film transistor 11, the gate line 12, and the data line 13 are formed. As shown in FIG. 1, an orthographic projection of the first passivation layer 14 substantially completely covers the base substrate 1.The reflective layer 15 is formed on the first passivation layer 14, and the reflective layer 15 may cover a region of the first passivation layer 14 corresponding to the first region 24 except the thin film transistor 11 and another region of the first passivation layer 14 corresponding to at least a portion of the thin film transistor 11. For example, the reflective layer 15 may substantially cover a region of the first passivation layer 14 corresponding to the first region 24 except the thin film transistor 11 and another region of the first passivation layer 14 corresponding to the drain 115 of the thin film transistor 11. Alternatively, the reflective layer 15 may substantially cover a region of the first passivation layer 14 corresponding to the first region 24, in this case, the reflective layer 15 substantially covers a region of the first passivation layer 14 corresponding to the first region 24 except the thin film transistor 11 and another region of the first passivation layer 14 corresponding to the thin film transistor 11.

The thin film transistor 11 is disposed between the reflective layer 15 and the base substrate 1, and the reflective layer 15 covers the first region except the thin film transistor 11 and at least a portion of the thin film transistor 11. Thus the light incident on the thin film transistor 11 can also be reflected by the reflective layer 15 such that an effective display region of the pixel region includes the first region except the thin film transistor 11 and at least a portion of the thin film transistor 11. Compared with an effective display region, which only includes the first region except the thin film transistor, of a pixel region in the related art, the area of the effective display region of the pixel region is increased, thereby increasing an aperture ratio of the display device.

In an embodiment of the present disclosure, as shown in FIGS. 1-3, the array substrate further includes a black matrix 17 disposed on a side of the thin film transistor 11 facing away from the base substrate 1. The black matrix 17 may prevent the light leakage between two adjacent pixel regions, thereby improving the contrast of the display device and improving the display quality of the display device. The black matrix 17 corresponds to the gate lines 12 and the data lines 13, respectively, and defines a plurality of opening regions 25. The opening regions 25 define the sizes of the pixel regions, and the opening regions 25 are in one-to-one correspondence with the first regions 24. The reflective layer 15 and the filter layer 18 are both disposed in one of the plurality of opening regions 25, and an orthographic projection of each of the reflective layer 15 and the filter layer 18 on the base substrate substantially coincides with an orthographic projection of the one of the plurality of opening regions 25 on the base substrate.

In an example, an orthographic projection of each of the first regions 24 on the base substrate coincides with an orthographic projection of a corresponding opening region 25 on the base substrate. Specifically, referring to FIG. 2, an orthogonal projection of a portion of the black matrix 17 corresponding to the gate line 12 on the base substrate 1 coincides with an orthographic projection of the gate line 12 on the base substrate 1, in other words, a width of the portion of the black matrix 17 corresponding to the gate line 12 is equal to a width of the gate line 12. Also, an orthographic projection of a portion of the black matrix 17 corresponding to the data line 13 on the base substrate 1 coincides with an orthographic projection of the data line 13 on the base substrate 1, in other words, a width of the portion of the black matrix 17 corresponding to the data line 13 is equal to the width of the data line 13. In this case, the area of each of the opening regions 25 is equal to the area of each of the first regions. In this way, the effective display region of the pixel region includes the first region except the thin film transistor 11 and at least a portion of the thin film transistor 11. Compared with the effective display region, which only includes the first region except the thin film transistor, of a pixel region in the related art, the area of the effective display region of the pixel region is increased, thereby increasing an aperture ratio of the display device.

In another example of the present disclosure, an orthographic projection of each of first regions 24 on the base substrate falls within an orthographic projection of the corresponding opening region 25 on the base substrate. Specifically, referring to FIG. 3, an orthographic projection of a portion of the black matrix 17 corresponding to the gate line 12 on the base substrate 1 falls within an orthographic projection of the gate line 12 on the base substrate 1, in other words, a width of the portion of the back matrix 17 corresponding to the gate line 12 is smaller than a width of the gate line 12; and/or an orthographic projection of a portion of the black matrix 17 corresponding to the data line 13 on the base substrate 1 falls within an orthographic projection of the data line 13 on the base substrate 1, in other words, a width of the portion of the black matrix 17 corresponding to the data line 13 on the base substrate 1 is smaller than a width of the data line 13. In this case, the area of each of the opening regions 25 is larger than the area of each of the first regions 24. In this way, the areas of the reflective layer 15 and the filter layer 18 located in the opening region 25 are larger than the area of the first region, and the effective display region of the pixel region includes the entire first region and at least a portion of the gate line and/or at least a portion of the data line. The area of the effective display region of the pixel region is further increased, thereby further increasing an aperture ratio of the display device.

In this embodiment, the position of the black matrix 17 can be set according to the structure of the reflective layer 15. For example, referring to FIG. 1, a first passivation layer 14 is disposed between the thin film transistor 11 and the reflective layer 15, and the first passivation layer 14 completely covers the base substrate 1. The reflective layer 15 is located on the first passivation layer 14 and only covers the first region 24 except the thin film transistor 11 and at least a portion of the thin film transistor 11. In this case, the black matrix 17 may be formed on the first passivation layer 14 together with the reflective layer 15, that is, the black matrix 17 and the reflective layer 15 are both disposed on the first passivation layer 14 and adjacent to each other, and both of them are in direct contact with the first passivation layer 14.

In the embodiment, referring to FIG. 1, the drain electrode 115 of the thin film transistor is electrically connected to the pixel electrode 23 through an via hole 31. The via hole penetrates through the first passivation layer 14, the reflective layer 15, the filter layer 18, the third passivation layer 19 and the fourth passivation layer 22, and the pixel electrode 23 is electrically insulated from the reflective layer 15. In other embodiments, the pixel electrode 23 can also be electrically connected to the reflective layer 15.

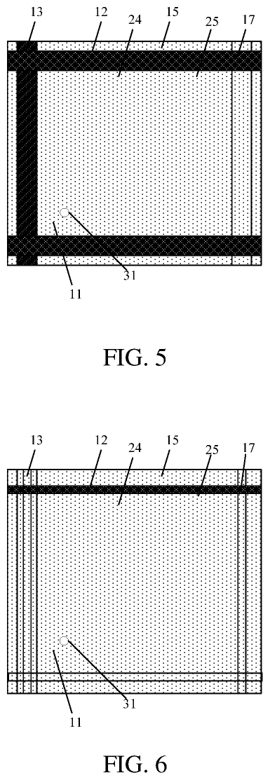

FIG. 4 is a schematic cross-sectional view of another array substrate according to an embodiment of the present disclosure, FIG. 5 is a schematic plan view showing a layout of a reflective layer of the array substrate of FIG. 4, and FIG. 6 is a schematic plan view showing a layout of a reflective layer of the array substrate of FIG. 4. Referring to FIGS. 4-6, compared with the foregoing embodiments, in another array substrate provided by an embodiment of the present disclosure, the reflective layer 15 substantially completely covers the base substrate 1. It can be understood that the reflective layers of the plurality of pixels are connected to each other to form an integrated continuous reflective layer, and the integrated continuous reflective layer substrate substantially completely covers the entire base substrate of the array substrate. Specifically, the array substrate provided in this embodiment includes a plurality of first regions 24 defined by a plurality of gate lines 12 and a plurality of data lines 13 crossing each other, one thin film transistor 11 is provided in each of the first regions 24, and each of the first regions 24 corresponds to a pixel electrode 23 and a common electrode 21. The thin film transistor 11 is formed in the first region 24 on the base substrate 1 and includes a gate electrode 111, a gate insulating layer 112, an active layer 113, and a source electrode 114 and a drain electrode 115. The gate electrode 111 is disposed in the same layer as the gate lines 12, and the gate electrode 111 is electrically connected to a corresponding gate line 12. The gate insulating layer 112 covers the gate electrode 111, the gate line 12 and the base substrate 1. It can also be understood that the gate insulating layer 112 substantially completely covers the base substrate 1 on which the gate electrode 111 and the gate line 12 are formed. As shown in FIG. 4, an orthographic projection of the gate insulating layer 112 on the base substrate 1 substantially completely covers the base substrate 1. The source electrode 114 and the drain electrode 115 are disposed in the same layer as the data lines 13, and the source electrode 114 is electrically connected to a corresponding data line 13, the drain electrode 115 is electrically connected to a corresponding pixel electrode 23. A first passivation layer 14 is formed on the thin film transistor 11. The first passivation layer 14 covers the source electrode 114, the drain electrode 115, the active layer 113, the data line 13, the gate line 12, and the gate insulating layer 112. It can also be understood that the first passivation layer 14 substantially completely covers the base substrate 1 on which the thin film transistor 11, the gate line 12, and the data line 13 are formed. As shown in FIG. 4, an orthographic projection of the first passivation layer 14 on the base substrate 1 completely covers the base substrate 1, the reflective layer 15 is formed on the first passivation layer 14 and substantially completely covers the first passivation layer 14, and it can also be understood that the reflective layer 15 substantially completely covers the base substrate 1. Referring to FIG. 4, an orthographic projection of the reflective layer 15 on the base substrate 1 substantially completely covers the base substrate 1, and the orthographic projection of the reflective layer 15 on the base substrate 1 substantially coincides with the orthographic projection of the first passivation layer 14 on the base substrate 1. In this case, referring to FIGS. 5 and 6, the reflective layer 15 substantially covers the pixel regions, the gate lines, and the data lines.

The reflective layer 15 substantially completely covers the base substrate 1, thus the light incident on the thin film transistor 11 can also be reflected by the reflective layer 15, such that an effective display region of the pixel region substantially includes the whole first region 24. Compared with an effective display region, which only includes the first region except the thin film transistor, of a pixel region in the related art, the area of the effective display region of the pixel region is increased, thereby increasing an aperture ratio of the display device. In addition, the reflective layer 15 substantially completely covers the base substrate 1, which may improve the utilization of light incident on the array substrate, and improve the display quality of the display device.

In an embodiment of the present disclosure, as shown in FIG. 4-6, the array substrate further includes a black matrix 17 disposed on a side of the thin film transistor 11 facing away from the base substrate 1. The black matrix 17 may prevent the light leakage between two adjacent pixel regions, thereby improving the contrast of the display device and improving the display quality of the display device. The black matrix 17 corresponds to the gate lines 12 and the data lines 13, respectively, and defines a plurality of opening regions 25. The opening regions 25 define the sizes of the pixel regions, the opening regions 25 are in a one-to-one correspondence with the first regions 24, and an orthographic projection of the filter layer 18 on the base substrate substantially coincides with an orthographic projection of one of the plurality of opening regions 25 on the base substrate.

In an example, an orthographic projection of each of the first regions 24 on the base substrate coincides with an orthographic projection of a corresponding opening region 25 on the base substrate. Specifically, referring to FIG. 5, an orthogonal projection of a portion of the black matrix 17 corresponding to the gate line 12 on the base substrate 1 coincides with an orthographic projection of the gate line 12 on the base substrate 1, in other words, a width of the portion of the black matrix 17 corresponding to the gate line 12 is equal to a width of the gate line 12. Also, an orthographic projection of a portion of the black matrix 17 corresponding to the data line 13 on the base substrate 1 coincides with an orthographic projection of the data line 13 on the base substrate 1, in other words, a width of the portion of the black matrix 17 corresponding to the data line 13 is equal to the width of the data line 13. In this case, the area of each of the opening regions 25 is equal to the area of each of the first regions. In this way, the effective display region of the pixel region includes the first region 24 except the thin film transistor 11 and at least a portion of the thin film transistor 11. Compared with the effective display region, which only includes the first region except the thin film transistor, of a pixel region in the related art, the area of the effective display region of the pixel region is increased, thereby increasing an aperture ratio of the display device.

In another example of the present disclosure, an orthographic projection of each first region 24 on the base substrate falls within an orthographic projection of the corresponding opening region 25 on the base substrate. Specifically, referring to FIG. 6, an orthographic projection of a portion of the black matrix 17 corresponding to the gate line 12 on the base substrate 1 falls within an orthographic projection of the gate line 12 on the base substrate 1, in other words, a width of the portion of the back matrix 17 corresponding to the gate line 12 is smaller than a width of the gate line 12; and/or an orthographic projection of a portion of the black matrix 17 corresponding to the data line 13 on the base substrate 1 falls within an orthographic projection of the data line 13 on the base substrate 1, in other words, a width of the portion of the black matrix 17 corresponding to the data line 13 on the base substrate 1 is smaller than a width of the data line 13. In this case, the area of each of the opening regions 25 is larger than the area of each of the first regions 24. In this way, the area of the filter layer 18 located in the opening region 25 are larger than the area of the first region, and the effective display region of the pixel region includes the entire first region and at least a portion of the gate line and/or at least a portion of the data line. The area of the effective display region of the pixel region is further increased, thereby further increasing an aperture ratio of the display device.

In the embodiment, the position of the black matrix 17 can be set according to the structure of the reflective layer 15. For example, referring to FIG. 4, a first passivation layer 14 is disposed between the thin film transistor 11 and the reflective layer 15, and the first passivation layer 14 substantially completely covers the base substrate 1. The reflective layer 15 is located on the first passivation layer 14 and substantially completely covers the base substrate 1. It is also understood that the reflective layer 15 is located on the first passivation layer 14 and covers the entire first passivation layer 14. In this case, a second passivation layer 16 is formed on the reflective layer 15, and substantially completely covers the reflective layer 15, and it can also be understood that the second passivation layer 16 substantially completely covers the base substrate 1. The black matrix 17 is located on the second passivation layer 16, the filter layer 18 is also located on the second passivation layer 16, and the black matrix 17 may be formed on the second passivation layer 16 together with the filter layer 18. The black matrix 17 and the filter layer 18 are both disposed on the second passivation layer 16 and adjacent to each other, and both of them are in direct contact with the second passivation layer 16.

In the embodiment, referring to FIG. 4, the drain electrode 115 of the thin film transistor is electrically connected to the pixel electrode 23 through an via hole 31. The via hole penetrates through the first passivation layer 14, the reflective layer 15, the filter layer 18, the third passivation layer 19 and the fourth passivation layer 22, and the pixel electrode 23 is electrically insulated from the reflective layer 15.

It should be noted that, in the above embodiments, orthographic projections of the pixel electrode 23 and the common electrode 21 disposed in the pixel region on the base substrate 1 may not cover the orthographic projection of the thin film transistor 11 on the base substrate 1. Alternatively, as shown in FIG. 1 or FIG. 4, an orthographic projection of at least one of the pixel electrode 23 and the common electrode 21 on the base substrate 1 may cover at least a portion of the orthographic projection of the thin film transistor 11 on the base substrate 1. For example, an orthographic projection of each of the pixel electrode 23 and the common electrode 21 on the base substrate 1 may substantially completely covers the orthographic projection of the thin film transistor 11 on the base substrate 1, so that an coverage area of an electric field generated between the pixel electrode 23 and the common electrode 21 may be increased, thereby increasing an area of the effective display region of the pixel region and increasing the aperture ratio of the display device. Moreover, the utilization of light incident into the array substrate is enhanced, and the picture display quality of the display device is improved.

It should be noted that the plurality of common electrodes 21 corresponding to the plurality of first regions 24 may be connected to each other as one integral transparent electrode, and a positional relationship between the pixel electrode 24 and the common electrode 21 is not limited to the case shown in FIGS. 1 and 4, and the positions of the two are interchangeable.

It should be noted that the reflective layer 15 may be made of various materials. For example, the reflective layer 15 may be made of an organic material, an inorganic material, a metal, or the like having a reflective function. In an embodiment of the present disclosure, the reflective layer 15 is made of metal, that is, the reflective layer 15 is a metal reflective layer.

It should be noted that the filter layer 18 may be made of a color resin. Specifically, in an embodiment, the material of the filter layer 18 of the array substrate includes a red resin, a green resin, and a blue resin, and the red resin is deposited in a pixel used for displaying red, the green resin is deposited in a pixel region used for displaying green, and the blue resin is deposited in a pixel region used for displaying blue.

An embodiment of the present disclosure provides a display panel, which includes the array substrate provided by the foregoing embodiments. Specifically, the display panel provided by the embodiment of the present disclosure includes the array substrate provided in the above embodiment, and an opposite substrate in parallel with and opposite to the array substrate. The array substrate may adopt the array substrate shown in FIG. 1, in which the reflective layer 15 only covers the first region except the thin film transistor 11 and at least a portion of the thin film transistor 11, alternatively, the array substrate may also adopt the array substrate shown in FIG. 4, in which the reflective layer 15 substantially completely covers the base substrate 1.

Compared with the prior art, the display panel provided in this embodiment has the same advantages as the array substrate provided in the above embodiments, and details are not described herein again.

An embodiment of the present disclosure provides an array substrate, different from the array substrate in the foregoing embodiments, the common electrode 21 is not disposed on the array substrate. The array substrate in this embodiment is, for example, a TN (Twisted Nematic) mode or an MVA (Multi-domain Vertical Alignment) mode array substrate.

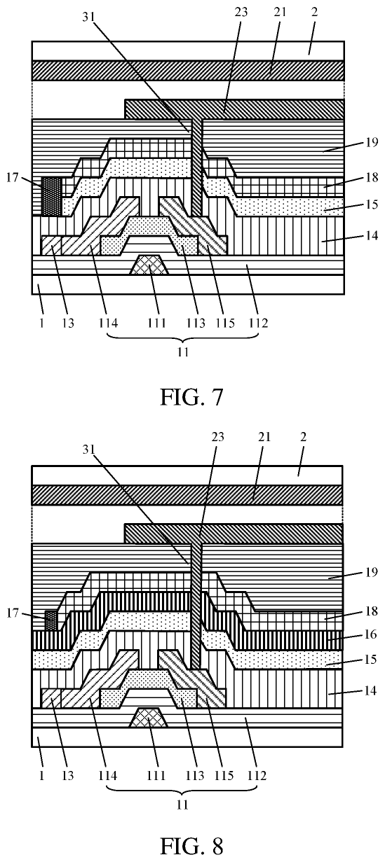

Specifically, referring to FIG. 7 and FIG. 8, the array substrate provided in the embodiment includes a base substrate 1 and a reflective layer 15, a filter layer 18, and a pixel electrode 23 which are sequentially disposed on the base substrate 1.

In the array substrate provided in this embodiment, the reflective layer 15, the filter layer 18, and the pixel electrode 23 are sequentially disposed on the base substrate 1. A common electrode 21 is disposed on an opposite substrate 2 disposed in parallel with and opposite to the array substrate. When a display panel including the array substrate provided by the present disclosure is in operation, a voltage is applied between the pixel electrode 23 and the common electrode 21, an electric field generated between the pixel electrode 23 and a common electrode 21 does not pass through the filter layer 18, therefore, the filter layer does not adversely affect the electric field generated between the pixel electrode 23 and the common electrode 21, so that the voltage required to drive the liquid crystal molecules to deflect can be reduced, thereby reducing the power consumption of the display panel.

In addition, in the array substrate provided in the embodiment, the reflective layer 15 functions only to reflect light, and does not function as, for example, an electrode. The reflective layer 15 has a single function, so that the structure of the reflective layer 15 can be conveniently set, and it is also possible to prevent the reflective layer from adversely affecting the potential of the pixel electrode 23 or the common electrode 21 when the reflective layer 15 functions as an electrode.

In this embodiment, the structure of the reflective layer 15 can be set according to actual needs. For example, referring to FIG. 7, the reflective layer 15 can adopt a structure similar to the reflective layer 15 of the array substrate shown in FIGS. 1-3. Specifically, the array substrate provided in the embodiment further includes a plurality of first regions 24 defined by a plurality of gate lines 12 and a plurality of data lines 13 crossing each other. One thin film transistor 11 is disposed in each of the first regions 24, and each of the first regions 24 corresponds to one pixel electrode 23. The thin film transistor 11 is located between the base substrate 1 and the reflective layer 15. A gate electrode 111 of the thin film transistor 11 is electrically connected to a corresponding gate line 12, and a source electrode 114 of the thin film transistor 11 is electrically connected to a corresponding data line 13, and a drain electrode 115 of the thin film transistor 11 is electrically connected to a corresponding pixel electrode 23. The reflective layer 15 covers the first region 24 except the thin film transistor 11 and at least a portion of the thin film transistor 11, and the filter layer 18 also covers the first region 24 except the thin film transistor 11 and at least a portion of the thin film transistor 11. An orthographic projection of the filter layer 18 on the base substrate 1 substantially coincides with an orthographic projection of the reflective layer 15 on the base substrate 1.

In an embodiment of the present disclosure, referring to FIG. 7, and further referring to FIGS. 2 and 3, the array substrate further includes a black matrix 17 on a side of the thin film transistor 11 facing away from the base substrate 1, the black matrix 17 can prevent the light leakage between the adjacent two pixel regions, thereby improving the contrast of the display device and improving the display quality of the display device. The black matrix 17 corresponds to the gate line 12 and the data line 13, respectively, and defines a plurality of opening regions 25. The opening regions 25 define the sizes of the pixel regions, and each of the opening regions 25 corresponding to one first region 24. The reflective layer 15 and the filter layer 18 are both disposed in one of the plurality of opening regions 25, and an orthographic projection of each of the reflective layer 15 and the filter layer 18 on the base substrate substantially coincides with an orthographic projection of the one of the plurality of opening regions 25 on the base substrate.

In an example, an orthographic projection of each of the first regions 24 on the base substrate coincides with an orthographic projection of a corresponding opening region 25 on the base substrate, In this case, the area of each of the opening regions 25 is equal to the area of each of the first regions. In this way, the effective display region of the pixel region includes the first region except the thin film transistor 11 and at least a portion of the thin film transistor 11. Compared with the effective display region, which only includes the first region except the thin film transistor, of a pixel region in the related art, the area of the effective display region of the pixel region is increased, thereby increasing an aperture ratio of the display device.

In another example of the present disclosure, an orthographic projection of each of first regions 24 on the base substrate falls within an orthographic projection of a corresponding opening region 25 on the base substrate. In this case, the area of each of the opening regions 25 is larger than the area of each of the first regions 24. In this way, the areas of the reflective layer 15 and the filter layer 18 located in the opening region 25 are larger than the area of the first region, and the effective display region of the pixel region includes the entire first region and at least a portion of the gate line and/or at least a portion of the data line. The area of the effective display region of the pixel region is further increased, thereby further increasing an aperture ratio of the display device.

In this embodiment, the position of the black matrix 17 can be set according to the structure of the reflective layer 15. For example, referring to FIG. 7, a first passivation layer 14 is disposed between the thin film transistor 11 and the reflective layer 15, and the first passivation layer 14 completely covers the base substrate 1. The reflective layer 15 is located on the first passivation layer 14 and only covers the first region 24 except the thin film transistor 11 and at least a portion of the thin film transistor 11. In this case, the black matrix 17 may be formed on the first passivation layer 14 together with the reflective layer 15, that is, the black matrix 17 and the reflective layer 15 are both disposed on the first passivation layer 14 and adjacent to each other, and both of them are in direct contact with the first passivation layer 14.

According to another embodiment of the present disclosure, referring to FIG. 8, the reflective layer 15 may adopt a structure of the reflective layer 15 as shown in FIGS. 4-6. Specifically, the display panel provided by the embodiment further includes a plurality of first regions 24 defined by a plurality of gate lines 12 and a plurality of data lines 13 crossing each other. One thin film transistor 11 is provided in each of the first regions 24, and each of the first regions 24 corresponds to a pixel electrode 23. The thin film transistor 11 is located between the base substrate 1 and the reflective layer 15. A gate electrode 111 of the thin film transistor 11 is electrically connected to a corresponding gate line 12, a source electrode 114 of the thin film transistor 11 is electrically connected to a corresponding data line 13, and a drain electrode 115 of the thin film transistor 11 is electrically connected to a corresponding pixel electrode 23. The reflective layer 15 substantially completely covers the base substrate 1. As shown in FIG. 8, an orthographic projection of the reflective layer 15 on the base substrate 1 completely covers the base substrate 1, that is, the reflective layer 15 completely covers the first region and the gate lines 12 and the data lines 13; the filter layer 18 covers the first region except the thin film transistor 11 in the first region and at least a portion of the thin film transistor 11.

In an embodiment of the present disclosure, referring to FIG. 8 and further referring to FIGS. 5 and 6, the array substrate further includes a black matrix 17 on a side of the thin film transistor 11 facing away from the base substrate 1. The black matrix 17 may prevent the light leakage between two adjacent pixel regions, thereby improving the contrast of the display device and improving the display quality of the display device. The black matrix 17 corresponds to the gate lines 12 and the data lines 13, respectively, and defines a plurality of opening regions 25. The opening regions 25 define the sizes of the pixel regions, each of the opening regions 25 corresponds to a first region 24, an orthographic projection of the filter layer 18 on the base substrate substantially coincides with an orthographic projection of one of the plurality of opening regions 25 on the base substrate.

In an example, an orthographic projection of each of the first regions 24 on the base substrate coincides with an orthographic projection of a corresponding opening region 25 on the base substrate. In this case, the area of each of the opening regions 25 is equal to the area of each of the first regions. In this way, the effective display region of the pixel region includes the first region 24 except the thin film transistor 11 and at least a portion of the thin film transistor 11. Compared with the effective display region, which only includes the first region except the thin film transistor, of a pixel region in the related art, the area of the effective display region of the pixel region is increased, thereby increasing an aperture ratio of the display device.

In another example of the present disclosure, an orthographic projection of each first region 24 on the base substrate falls within an orthographic projection of the corresponding opening region 25 on the base substrate. In this case, the area of each of the opening regions 25 is larger than the area of each of the first regions 24. In this way, the area of the filter layer 18 located in the opening region 25 are larger than the area of the first region, and the effective display region of the pixel region includes the entire first region and at least a portion of the gate line and/or at least a portion of the data line. The area of the effective display region of the pixel region is further increased, thereby further increasing an aperture ratio of the display device

In the embodiment, the position of the black matrix 17 can be set according to the structure of the reflective layer 15. For example, referring to FIG. 8, a first passivation layer 14 is disposed between the thin film transistor 11 and the reflective layer 15, and the first passivation layer 14 substantially completely covers the base substrate 1. The reflective layer 15 is located on the first passivation layer 14 and substantially completely covers the base substrate 1. It is also understood that the reflective layer 15 is located on the first passivation layer 14 and covers the entire first passivation layer 14. In this case, a second passivation layer 16 is formed on the reflective layer 15, and substantially completely covers the reflective layer 15, and it can also be understood that the second passivation layer 16 substantially completely covers the base substrate 1. The black matrix 17 is located on the second passivation layer 16, the filter layer 18 is also located on the second passivation layer 16, and the black matrix 17 may be formed on the second passivation layer 16 together with the filter layer 18. The black matrix 17 and the filter layer 18 are both disposed on the second passivation layer 16 and adjacent to each other, and both of them are in direct contact with the second passivation layer 16.

It should be noted that the reflective layer 15 may be made of various materials. For example, the reflective layer 15 may be made of an organic material, an inorganic material, a metal, or the like having a reflective function. In an embodiment of the present disclosure, the reflective layer 15 is made of metal, that is, the reflective layer 15 is a metal reflective layer.

It should be noted that the filter layer 18 may be made of a color resin. Specifically, in an embodiment, the material of the filter layer 18 of the array substrate includes a red resin, a green resin, and a blue resin, and the red resin is deposited in a pixel used for displaying red, the green resin is deposited in a pixel region used for displaying green, and the blue resin is deposited in a pixel region used for displaying blue.

An embodiment of the present disclosure provides a display panel. The display device includes the array substrate according to the foregoing embodiments, and the structure thereof is as shown in FIG. 7 or FIG. 8. The display panel further includes an opposite substrate 2 in parallel with and opposite to the array substrate. A common electrode 21 is disposed on a surface of the opposite substrate 2 facing the array substrate.

Compared with the prior art, the display panel provided in this embodiment has the same advantages as the array substrate provided in the above embodiments, and details are not described herein again.

It should be noted that the array substrate and the display panel provided in the above embodiments of the present disclosure can be applied to a reflective display device, for example, a flexible reflective display device or a rigid reflective display device. When the array substrate or the display panel provided by the embodiments of the present disclosure is applied to a flexible reflective display device, since the filter layer is disposed in the array substrate and is adjacent to the reflective layer, when the flexible reflective display device is bent, a deformation amount of the filter layer at the bending portion is substantially the same as a deformation amount of the reflective layer, thereby preventing the light leakage between adjacent two pixel regions in the flexible reflective display device.

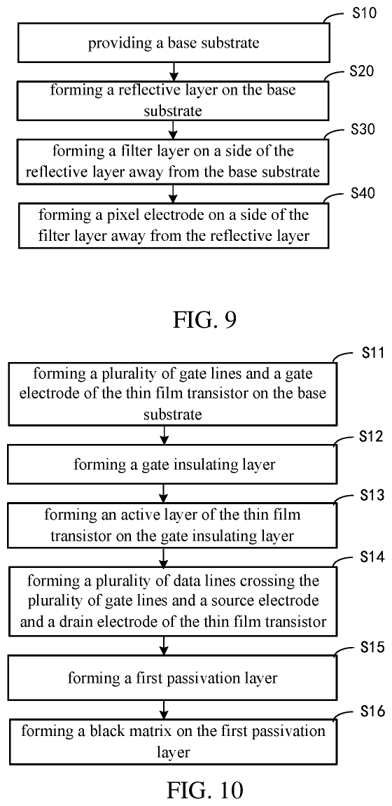

An embodiment of the present disclosure provides a method of manufacturing an array substrate for manufacturing the array substrates of the foregoing embodiments. As shown in FIG. 9, the method of manufacturing the array substrate includes:

Step S10, providing a base substrate;

Step S20, forming a reflective layer on the base substrate;

Step S30, forming a filter layer on a side of the reflective layer away from the base substrate; and

Step S40, forming a pixel electrode on a side of the filter layer away from the reflective layer.

In an array substrate manufactured by the method of the present embodiment, the pixel electrode is disposed on a side of the filter layer away from the reflective layer. When a display panel including the array substrate provided by the present disclosure is in operation, a voltage is applied between the pixel electrode and the common electrode, an electric field generated between the pixel electrode and a common electrode does not pass through the filter layer, therefore, the filter layer does not adversely affect the electric field generated between the pixel electrode and the common electrode, so that the voltage required to drive the liquid crystal molecules to deflect can be reduced, thereby reducing the power consumption of the display panel.

In an embodiment, after the step 10 of providing the base substrate, and before the step S20 of forming the reflective layer, the method of manufacturing the array substrate further includes: forming a thin film transistor on the base substrate. The reflective layer is disposed on a side of the thin film transistor away from the base substrate, and at least one of the reflective layer and the filter layer covers at least a portion of the thin film transistor.

In an embodiment, after the step S10 of providing the base substrate, and before the step S20 of forming the reflective layer, as shown in FIG. 10, the method of manufacturing the array substrate further includes:

Step S11, forming a plurality of gate lines and a gate electrode of the thin film transistor on the base substrate, and the plurality of gate lines and the gate electrode of the thin film transistor being simultaneously formed by the same patterning process;

Step S12, forming a gate insulating layer covering the base substrate on which the gate electrode and the gate lines are formed;

Step S13, forming an active layer of the thin film transistor on the gate insulating layer;

Step S14, forming a plurality of data lines crossing the plurality of gate lines and a source electrode and a drain electrode of the thin film transistor, the plurality of data lines as well as the source electrode and the drain electrode of the thin film transistor being simultaneously formed by the same patterning process, the source electrode and the drain electrode being both in contact with the active layer; and

Step S15, forming a first passivation layer covering the base substrate on which the gate insulating layer, the active layer, the source electrode, the drain electrode and the data lines are formed.

In an embodiment, before the step 20 of forming of the reflective layer, as shown in FIG. 10, the method of manufacturing the array substrate further includes:

Step S16, forming a black matrix on the first passivation layer.

The black matrix defines a plurality of opening regions, and the reflective layer and the filter layer which are subsequently formed are formed in one of the plurality of opening regions. An orthographic projection of each of the reflective layer and the filter layer on the base substrate substantially coincides with an orthographic projection of the one of the plurality of opening regions on the base substrate.

In another embodiment, in the step S20, the reflective layer substantially completely covers the base substrate. After the step S20 of forming the reflective layer, and before the step S30 of forming the filter layer, as shown in FIG. 11, the method of manufacturing the array substrate further includes:

Step S21, forming a second passivation layer, the second passivation layer covering the reflective layer; and

Step S22, forming a black matrix on the second passivation layer.

The black matrix defines a plurality of opening regions, and the filter layer which is subsequently formed is formed in one of the plurality of opening regions. An orthographic projection of the filter layer on the base substrate substantially coincides with an orthographic projection of the one of the plurality of opening regions on the base substrate.

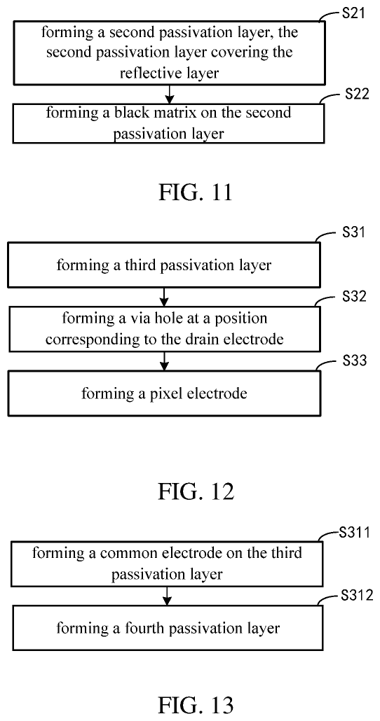

In an embodiment, after the step 30 of forming the filter layer, and before the step S40 of forming the pixel electrode, as shown in FIG. 12, the method of manufacturing the array substrate further includes:

Step S31, forming a third passivation layer, the third passivation layer substantially completely covering the base substrate on which the filter layer is formed;

Step S32, forming a via hole at a position corresponding to the drain electrode; and

Step S33, forming a pixel electrode, and the pixel electrode being electrically connected to the drain electrode through the via hole.

In another embodiment, after the step S31 of forming the third passivation layer, and before the step S32 of forming the via hole, as shown in FIG. 13, the method of manufacturing the array substrate further includes:

Step S311, forming a common electrode on the third passivation layer; and

Step S312, forming a fourth passivation layer, the fourth passivation layer substantially completely covering the base substrate on which the common electrode is formed.

Another embodiment of the present disclosure further provides a method of manufacturing a display panel. The method of manufacturing the display panel includes:

forming an array substrate by using the above method of manufacturing the array substrate;

providing an opposite substrate; and

aligning and assembling the array substrate and the opposite substrate.

In some embodiments, the common electrode is disposed on the opposite substrate, and the method of manufacturing the display panel further includes forming a common electrode on the opposite substrate.

The above is only the specific embodiment of the present disclosure, and the scope of the present disclosure is not limited thereto. Any changes or substitutions that may be easily conceived by any person skilled in the art within the scope of the present disclosure are intended to be included within the scope of protection of the present disclosure. Therefore, the scope of protection of the present disclosure should be determined by the scope of the claims.

1. An array substrate comprising:
a base substrate; and
a plurality of pixels on the base substrate,
at least one of the plurality of pixels comprising:
a reflective layer on the base substrate;
a filter layer on a side of the reflective layer away from the base substrate; and
a pixel electrode on a side of the filter layer away from the reflective layer.

2. The array substrate of claim 1, wherein the at least one of the plurality of pixels further comprises:
a thin film transistor between the base substrate and the reflective layer,
wherein at least one of the reflective layer and the filter layer covers at least a portion of the thin film transistor.

3. The array substrate of claim 2, further comprising:
a plurality of gate lines;
a plurality of data lines crossing the plurality of gate lines; and
a black matrix on a side of the thin film transistor away from the base substrate,
wherein the plurality of data lines and the plurality of gate lines crossing each other define a plurality of first regions, the black matrix defines a plurality of opening regions, and an orthographic projection of each of the first regions on the base substrate falls within an orthographic projection of an corresponding one of the opening regions on the base substrate.

4. The array substrate of claim 2, further comprising:
a plurality of gate lines;
a plurality of data lines crossing the plurality of gate lines; and
a black matrix on a side of the thin film transistor away from the base substrate,
wherein the plurality of data lines and the plurality of gate lines crossing each other define a plurality of first regions, the black matrix defines a plurality of opening regions, and an orthographic projection of each of the first regions on the base substrate substantially coincides with an orthographic projection of an corresponding one of the opening regions on the base substrate.

5. The array substrate of claim 3, wherein the at least one of the plurality of pixels comprises one of the plurality of first regions and one of plurality of opening regions, and an orthographic projection of at least one of the reflective layer and the filter layer on the base substrate substantially coincides with an orthographic projection the one of the plurality of opening regions on the base substrate.

6. The array substrate of claim 5, wherein the reflective layer and the filter layer are both disposed in the one of the plurality of opening regions, and an orthographic projection of each of the reflective layer and the filter layer on the base substrate substantially coincides with the orthographic projection of the one of the plurality of opening regions on the base substrate.

7. The array substrate of claim 5, wherein reflective layers of the plurality of pixels are connected to each other to form an integrated continuous reflective layer, an orthographic projection of the integrated continuous reflective layer on the base substrate substantially completely covers the base substrate, and the black matrix and the filter layer are both disposed on a side of the integrated continuous reflective layer away from the base substrate, the filter layer is disposed in the one of the plurality of opening regions, the orthographic projection of the filter layer on the base substrate substantially coincides with the orthographic projection of the one of the plurality of opening regions on the base substrate.

8. The array substrate of claim 5, further comprising:
a common electrode on a side of the filter layer away from the reflective layer.

9. The array substrate of claim 1, wherein the reflective layer is a metal reflective layer.

10. A display panel comprising:
the array substrate of claim 1; and
an opposite substrate in parallel with and opposite to the array substrate, the opposite substrate being on a side of the pixel electrode away from the base substrate,
wherein a common electrode is disposed on a surface of the opposite substrate facing the array substrate.

11. A display panel comprising:
the array substrate of claim 8; and
an opposite substrate in parallel with and opposite to the array substrate, the
opposite substrate being on a side of both the pixel electrode and the common electrode away from the base substrate.

12. (canceled)

13. A method of manufacturing an array substrate, comprising:
providing a base substrate;
forming a reflective layer on the base substrate;
forming a filter layer on a side of the reflective layer away from the base substrate; and
forming a pixel electrode on a side of the filter layer away from the reflective layer.

14. The method of claim 13, wherein before forming a reflective layer on the base substrate, the method further comprises:
forming a thin film transistor on the base substrate,
wherein the reflective layer is disposed on a side of the thin film transistor away from the base substrate, and at least one of the reflective layer and the filter layer covers at least a portion of the thin film transistor.

15. The method of claim 14, further comprising:
forming a plurality of gate lines on the base substrate;
forming a plurality of data lines crossing the plurality of gate lines on the base substrate; and
forming a black matrix on the side of the thin film transistor away from the base substrate,
wherein the plurality of data lines and the plurality of gate lines crossing each other define a plurality of first regions, and the black matrix defines a plurality of opening regions,
wherein an orthographic projection of each of the first regions on the base substrate falls within an orthographic projection of an corresponding one of the opening regions on the base substrate, or the orthographic projection of each of the first regions on the base substrate substantially coincides with the orthographic projection of the corresponding one of the opening regions on the base substrate.

16. The method of claim 15, wherein the black matrix is formed before forming the reflective layer, and the reflective layer and the filter layer are both formed in one of the plurality of opening regions, and an orthographic projection of each of the reflective layer and the filter layer on the base substrate substantially coincides with the orthographic projection of the one of the plurality of opening regions on the base substrate.

17. The method of claim 15, wherein the black matrix is formed after forming the reflective layer and before forming the filter layer, and an orthographic projection of the reflective layer on the base substrate substantially completely covers the base substrate, and both the black matrix and the filter layer are disposed on a side of the reflective layer away from the base substrate, the filter layer is disposed in one of the plurality of opening regions, an orthographic projection of the filter layer on the base substrate substantially coincides with the orthographic projection of the one of the plurality of opening regions on the base substrate.

18. The method of claim 13, further comprising:
forming a common electrode on a side of the filter layer away from the reflective layer.

19-20. (canceled)

21. The array substrate of claim 4, wherein the at least one of the plurality of pixels comprises one of the plurality of first regions and one of the plurality of opening regions, and an orthographic projection of at least one of the reflective layer and the filter layer on the base substrate substantially coincides with an orthographic projection the one of the plurality of opening regions on the base substrate.

22. The array substrate of claim 7, further comprising:
a passivation layer between the integrated continuous reflective layer and the black matrix.

23. The array substrate of claim 8, wherein the common electrode is between the pixel electrode and the reflective layer.
